(19) United States
(12) Patent Application Publication
(10) Pub. No.: US 2026/0150457 A1
(43) Pub. Date: May 28, 2026

(54) Electronic device having dummy lens units

(71) Applicant: InnoLux Corporation, Miao-Li County (TW)

(72) Inventors: Yu-Chia Huang, Miao-Li County (TW); Tsung-Han Tsai, Miao-Li County (TW); Kuan-Feng Lee, Miao-Li County (TW)

(73) Assignee: InnoLux Corporation, Miao-Li County (TW)

(21) Appl. No.: 19/322,578

(22) Filed: Sep. 8, 2025

(30) Foreign Application Priority Data
Nov. 25, 2024 (CN) 202411689886.5

(51) Int. Cl. H10H 29/32; G02B 5/20; H10H 29/49; H10H 29/85; H10H 29/855

(52) U.S. Cl. CPC H10H 29/32; H10H 29/49; H10H 29/8517; H10H 29/855; G02B 5/201

(57) ABSTRACT

An electronic device has a substrate, a plurality of transistors, a first lens unit, and a second lens unit. The plurality of transistors are arranged on the substrate, and each transistor has a channel. The first lens unit and the second lens unit are arranged on the substrate. The quantity of channels of the plurality of transistors that overlap with the first lens unit is different from the quantity of channels of the plurality of transistors that overlap with the second lens unit.

### BACKGROUND OF THE DISCLOSURE

### 1. Field of the Disclosure

The disclosure relates to an electronic device, particularly to an electronic device with dummy lens units.

### 2. Description of the Prior Art

For special applications like car displays and projectors, electronic devices have increasingly stringent requirements for the brightness of the center viewing angle of display units. By placing micro-lenses on the light-emitting units, the display brightness can be effectively improved. However, the optical performance of micro-lenses is closely related to their shape. In traditional micro-lens manufacturing processes, the shape of micro-lenses often deviates due to the influence of the topography or layered structure where the micro-lenses are located.

### SUMMARY OF THE DISCLOSURE

According to some embodiments, the disclosure provides an electronic device having a substrate, a plurality of transistors, a first lens unit, and a second lens unit. The plurality of transistors are arranged on the substrate, and each of the transistors has a channel. The first lens unit and the second lens unit are arranged on the substrate. A quantity of channels of the plurality of transistors overlapping with the first lens unit is different from a quantity of channels of the plurality of transistors overlapping with the second lens unit

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a top view of an electronic device according to an embodiment of the disclosure.

FIG. 2 is a cross-sectional view of the electronic device in FIG. 1 taken along the dashed line 2-2′.

FIG. 3 is a top view of an electronic device according to another embodiment of the disclosure.

FIG. 4 is a cross-sectional view of the electronic device in FIG. 3 taken along the dashed line A-B-C-E in FIG. 3.

FIG. 5 is a top view of an electronic device according to another embodiment of the disclosure.

FIG. 6 is a cross-sectional view of the electronic device in FIG. 5 taken along the dashed line A-B-C-E in FIG. 5.

FIG. 7 is a top view of an electronic device according to another embodiment of the disclosure.

FIG. 8 is a cross-sectional view of the electronic device in FIG. 7 taken along the dashed line A-B-C-E in FIG. 7.

FIG. 9 is a cross-sectional view of an electronic device according to another embodiment of the disclosure.

FIG. 10 is a cross-sectional view of an electronic device according to another embodiment of the disclosure.

FIG. 11 is a top view of an electronic device according to another embodiment of the disclosure.

FIG. 12 is a cross-sectional view of the electronic device in FIG. 11 taken along the dashed line A-B-C in FIG. 11.

FIG. 13 is a cross-sectional view of an electronic device according to another embodiment of the disclosure.

FIG. 14 is a cross-sectional view of an electronic device according to another embodiment of the disclosure.

FIG. 15 is a top view of an electronic device according to another embodiment of the disclosure.

FIG. 16 is a cross-sectional view of an electronic device according to another embodiment of the disclosure.

FIG. 17 is a cross-sectional view of an electronic device according to another embodiment of the disclosure.

FIG. 18 is a cross-sectional view of two electronic devices according to another embodiment of the disclosure.

### DETAILED DESCRIPTION

By referring to the following detailed description in conjunction with the accompanying drawings, the present disclosure can be understood. It should be noted that, for the sake of clarity and conciseness, the drawings in the disclosure only depict a portion of the electronic device, and specific elements in the drawings are not drawn to actual scale. Furthermore, the quantity and size of elements in the figures are merely illustrative and are not intended to limit the scope of the present disclosure.

Throughout the disclosure and the appended claims, certain terms are used to refer to specific elements. Those skilled in the art should understand that manufacturers of electronic devices may refer to the same elements by different names. This document is not intended to distinguish between elements that perform the same functions but are named differently.

In the following description and patent claims, terms like “comprising,” “including,” and “having” are open-ended terms, and therefore should be interpreted to mean “including but not limited to . . . ”. Thus, when terms like “comprising,” “including,” and/or “having” are used in the descriptions of the disclosure, they specify the presence of corresponding features, regions, steps, operations, and/or components, but do not exclude the presence of one or more corresponding features, regions, steps, operations, and/or components.

Directional terms mentioned herein, such as “upper,” “lower,” “front,” “rear,” “left,” “right,” etc., are merely references to the directions shown in the figures. Therefore, the directional terms used are for illustrative purposes and are not intended to limit the present disclosure. In the drawings, each figure depicts the general characteristics of methods, structures, and/or materials used in specific embodiments. However, these figures should not be interpreted as defining or limiting the scope or nature covered by these embodiments. For example, for clarity, the relative sizes, thicknesses, and positions of various layers, regions, and/or structures may be reduced or enlarged.

When a corresponding component (e.g., a layer or a region) is described as being “on another component,” it can be directly on the other component, or there can be intervening components between them. On the other hand, when a component is described as being “directly on another component,” there are no intervening components between them. Additionally, when a component is described as being “on another component,” it indicates an up-and-down relationship in the vertical direction, and this component can be above or below the other component, depending on the orientation of the device.

It should be understood that when a component or layer is described as being “connected to” another component or layer, it can be directly connected to this other component or layer, or there can be intervening components or layers. When a component is described as being “directly connected to” another component or layer, there are no intervening components or layers between them. Additionally, when a component is described as being “coupled to another component (or its variant),” it can be directly electrically connected to this other component or indirectly connected (e.g., indirectly electrically connected) through one or more components.

In the disclosure, when a component is “disconnected” from another component, electrical signals cannot flow between the two components at the specified time.

The term “approximately” or “about” is generally interpreted as being within ±10% of the given value or interpreted as being within ±5%, ±3%, ±2%, ±1%, or ±0.5% of the given value.

The ordinal numbers such as “first,” “second,” etc., used in the description and patent claims to modify elements do not imply any particular sequence of those elements or any manufacturing method sequence. These ordinal numbers are only used to distinguish elements with a certain naming from other elements with the same naming. Thus, the “first element” in the description might be the “second element” in the claims.

It should be noted that the features of different embodiments cited below can be replaced, reorganized, or mixed to complete other embodiments without departing from the spirit of the present disclosure. As long as the features of each embodiment do not conflict with each other or with the spirit of the invention, they can be mixed and matched as desired.

In the disclosure, the electronic device may include display devices, light-emitting devices, antenna devices, sensing devices, splicing devices, or any combination thereof, but is not limited to these. The display device can be a non-self-luminous or self-luminous display, and can be a color or monochrome display according to the demand. The antenna device can be a liquid crystal type antenna device or a non-liquid crystal type antenna device. The sensing device can be a sensing device for capacitance, light, heat, or ultrasonic waves. The splicing device can be a display splicing device or an antenna splicing device, but is not limited to these. The electronic device may include electronic components, which can include passive components and active components such as capacitors, resistors, inductors, diodes, transistors, die, integrated circuits (ICs), sensors, redistribution layers (RDLs), or chips. Diodes may be dies or chips and may include light-emitting diodes (LEDs), photodiodes, or variable capacitors (varactors), but are not limited to these. LEDs may include organic LEDs (OLEDs), mini LEDs, micro LEDs, or quantum dot LEDs (QLEDs), but are not limited to these. Transistors may include top-gate thin-film transistors, bottom-gate thin-film transistors, or dual-gate thin-film transistors, but are not limited to these. The electronic device may also include materials such as fluorescence materials, phosphor materials, quantum dot (QD) materials, or other suitable materials, but is not limited to these. The electronic device may have peripheral systems such as driving systems, control systems, light source systems, and others to support the devices and components in the electronic device.

It should be noted that the technical features in different embodiments described below can be replaced, reorganized, or mixed with each other without departing from the spirit of the present disclosure to form another embodiment.

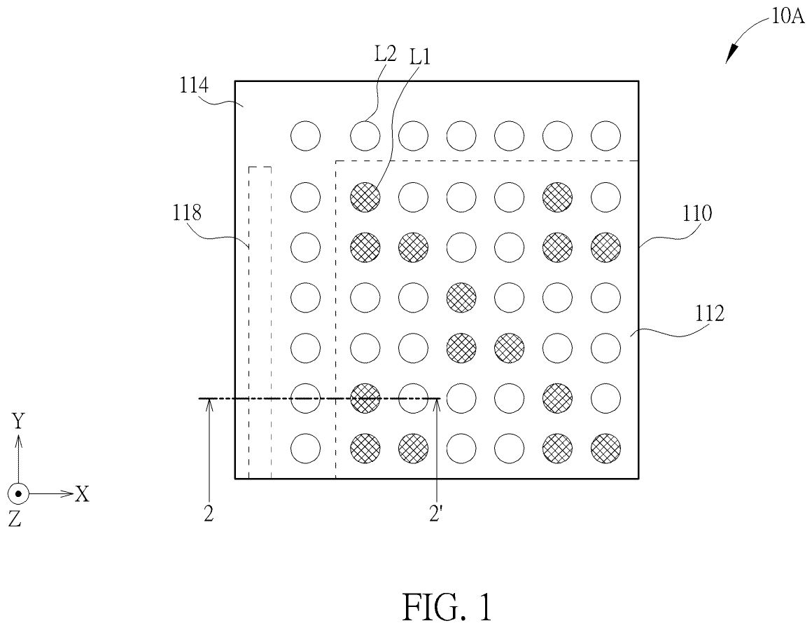

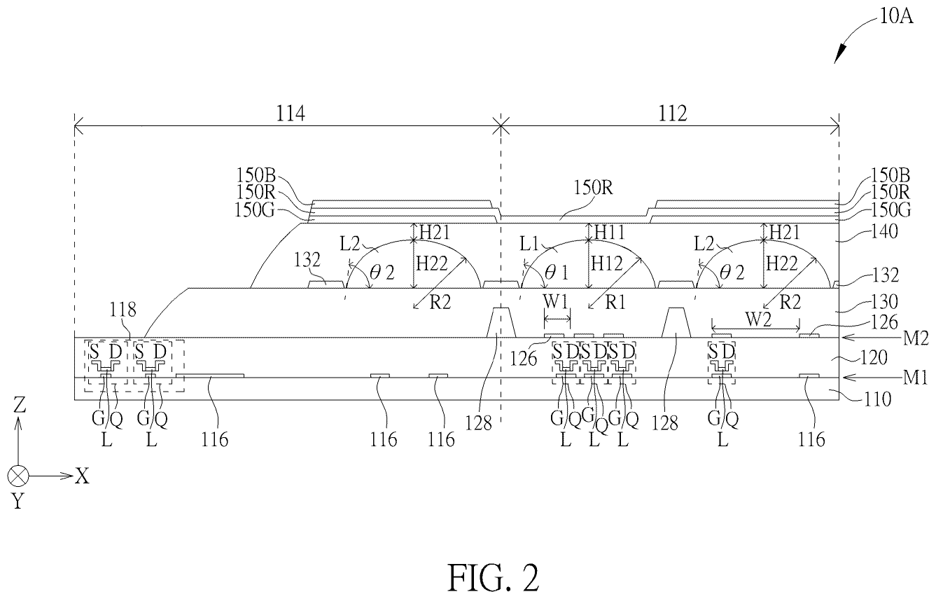

Please refer to FIG. 1 and FIG. 2. FIG. 1 is a top view of an electronic device 10A according to one embodiment of the disclosure, and FIG. 2 is a cross-sectional view of the electronic device 10A in FIG. 1 taken along the dashed line 2-2′. In FIG. 1, the top view extends along direction X and direction Y, and in FIG. 2, the cross-sectional view extends along direction X and direction Z, and the directions X, Y, and Z can be mutually perpendicular. The electronic device 10A comprises a substrate 110, a plurality of transistors Q, at least one lens unit L1, and at least one lens unit L2. Each transistor Q is arranged on the substrate 110 and has a channel L. The lens units L1 and L2 are both arranged on the substrate 110, and the number of channels L overlapping with the lens unit L1 is different from the number of channels L overlapping with any of the lens units L2. Whether the lens unit L1 or L2 overlap with the channels L is determined in a top view along direction Z. If the channel L of any transistor Q overlaps with the lens unit L1 or L2 in the top view of FIG. 1, the number of channels overlapping with the lens unit L1 or L2 would be incremented. As seen from FIG. 2 in this embodiment, the number of channels L overlapping with the lens unit L1 in FIG. 2 is three, while the numbers of channels L overlapping with the two lens units L2 in FIG. 2 are zero and one, respectively. Furthermore, in this embodiment, the number of channels L overlapping with any lens unit L1 is greater than the number of channels L overlapping with any lens unit L2 in all transistors Q. However, the disclosure is not limited thereto. In other embodiments, the number of channels L overlapping with any lens unit L1 can be less than the number of channels L overlapping with any lens unit L2 in all transistors Q. The structural strength of electronic device 10A can be enhanced by the arrangement of the lens units L2.

Each transistor Q may comprise a gate G, a source S, and a drain D connected to a semiconductor layer, with a channel L formed between the source S and the drain D. The channel L is an overlapping area of gate G and the semiconductor layer of transistor Q in the top view of the electronic device 10A. The area of electronic device 10A can be divided into an active region 112 and a peripheral region 114 adjacent to the active region 112. The active region 112 is the main operating area and/or the user-operating area of the main components of the electronic device 10A, such as the location of light-emitting units generating light, electromagnetic components sending and/or receiving electromagnetic waves, and touch-sensitive elements. The peripheral region 114 is the area of the electronic device 10A other than the active region 112. In this embodiment, the lens unit L1 can be arranged in the active region 112, and the lens unit L2 can be partially arranged in the peripheral region 114 and partially in the active region 112. The electronic device 10A may further comprise a driving circuit 118 and a conductive layer M1. The driving circuit 118 can be, but not limited to, a gate driver circuit, including a plurality of transistors Q. The conductive layer M1 is arranged on the substrate 110 and has a plurality of conductive lines 116. The conductive lines 116 may be connected to the driving circuit 118 or serve as bridging parts between other signal lines or act as shading structures, but are not limited thereto. The driving circuit 118 can drive the transistors Q arranged in the active region 112 through the conductive lines 116. The electronic device 10A may further comprise an insulating layer 120 arranged on the substrate 110 and covering the driving circuit 118 and the conductive layer M1. The electronic device 10A may further comprise a conductive layer M2 arranged on the insulating layer 120 and having a plurality of conductive lines 126. The conductive lines 126 can be used to connect part of the signal lines or act as shading structures but are not limited thereto. Among the plurality of conductive lines 126, the pitch W1 of two adjacent conductive lines 126 located under the lens unit L1 is smaller than the pitch W2 of two other adjacent conductive lines 126 located under the lens unit L2. The pitch W1 and pitch W2 refer to the distance between the same sides of two adjacent conductive lines 126, for example, as shown in FIG. 2, the pitch W1 and pitch W2 refer to the distance between the left sides of two adjacent conductive lines 126. In other embodiments, the pitch between conductive lines 126 can refer to the distance between the centers of two adjacent conductive lines 126. The electronic device 10A may further comprise a definition layer 128 arranged on the insulating layer 120. The definition layer 128 can be, but not limited to, a pixel definition layer (PDL). The electronic device 10A may further comprise an insulating layer 130 arranged on the insulating layer 120 and covering the definition layer 128 and the conductive layer M2. In this embodiment, the lens units L1 and L2 are both arranged on the insulating layer 130. The electronic device 10A may further comprise a lens definition layer 132 arranged on the insulating layer 130 and formed between the lens units L1 and L2. The lens units L1 and L2 can be distinguished based on whether they overlap with light-emitting elements, the regions they are located in, or whether they overlap with shading elements. In some embodiments, the lens unit L1 overlaps with light-emitting elements (e.g., LEDs) in the cross-sectional view of the electronic device 10A, while the lens unit L2 does not overlap with light-emitting elements in the cross-sectional view of the electronic device 10A. In some embodiments, lens unit L1 is located in the active region 112, while lens unit L2 is located in the peripheral region 114. In some embodiments, there is no shading layer above the lens unit L1, while there is a shading layer above the lens unit L2. Additionally, each lens unit L2 can be referred to as a dummy lens unit. In the manufacturing process of the electronic device 10A, the lens definition layer 132 is formed first, followed by the formation of the lens units L1 and L2. The lens definition layer 132 can be a shielding layer, barrier layer, or can comprise a metal mesh arranged on the lens definition layer. The metal mesh can have a touch function and can be electrically connected to conductive lines 116 or 126 but is not limited thereto. The lens definition layer 132 can also be composed of hydrophilic or hydrophobic materials with different hydrophobicity from the surface of the insulating layer 130. In other embodiments, the lens definition layer 132 can be made of opaque materials. The electronic device 10A may further comprise an insulating layer 140 arranged on the insulating layer 130 and covering the lens units L1, L2, and the lens definition layer 132. The electronic device 10A may further comprise a plurality of color filters 150R, 150G, and 150B arranged on the insulating layer 140. The color filter 150R is a red color filter, the color filter 150G is a green color filter, and the color filter 150B is a blue color filter. One of the color filters 150R, 150G, and 150B is arranged on the lens unit L1, while at least two of the color filters 150R, 150G, and 150B are arranged on the lens unit L2. For example, in FIG. 2, a red color filter 150R is arranged on the lens unit L1, while each of the lens units L2 has a red color filter 150R, a green color filter 150G, and a blue color filter 150B. Since the three different color filters 150R, 150G, and 150B are arranged on the lens unit L2, the light from the lens unit L2 will be mostly filtered by the color filters 150R, 150G, and 150B, resulting in lower brightness in the area of the lens unit L2 compared to other areas of the electronic device 10A. Additionally, since only one color filter is arranged on the lens unit L1, the brightness in the area of the lens unit L1 will be higher than in the area of the lens unit L2 in the electronic device 10A. In FIG. 1, the electronic device 10A comprises a plurality of lens units L1, and the colors of the color filters on each lens unit L1 can be different. For example, the color filters 150R, 150G, and 150B can be arranged on three adjacent lens units L1, forming the red, green, and blue sub-pixels of the electronic device 10A, respectively. As shown in FIG. 2, the red color filter 150R on the lens unit L1 can be the same color filter as the red color filter 150R on the lens unit L2, overlapping with the green color filter 150G and the blue color filter 150B. The green color filter 150G completely overlaps with the red color filter 150R, while the red color filter 150R partially overlaps with the green color filter 150G and the blue color filter 150B. Additionally, the width of the lens unit L2 is smaller than the width of the color filters 150G and 150B. The width of the lens unit L2 refers to the maximum width measured along direction X, the width of the color filter 150G refers to the maximum width measured along direction X, and the width of the color filter 150B refers to the maximum width measured along direction X.

Furthermore, the height of the lens unit L1 is H12, the radius of curvature of the lens unit L1 is R1, the distance between the lens unit L1 and the color filter 150R is H11, and the contact angle between the lens unit L1 and the insulating layer 130 is θ1. The height of the lens unit L2 is H22, the radius of curvature of the lens unit L2 is R2, the distance between the lens unit L2 and the color filter 150G is H21, and the contact angle between the lens unit L2 and the insulating layer 130 is θ2. The height H12 can be equal to or different from H22, the radius of curvature R1 can be equal to or different from the radius of curvature R2, the distance H11 can be equal to or different from the distance H21, and the contact angle θ1 can be equal to or different from the contact angle θ2. Generally, the contact angles θ1 and θ2 can be greater than 30 degrees to avoid total internal reflection of light due to the lens units L1 and L2 being too flat. The contact angles θ1 and θ2 can also be less than 90 degrees to prevent side light leakage that causes deflection towards the sides of the electronic device 10A.

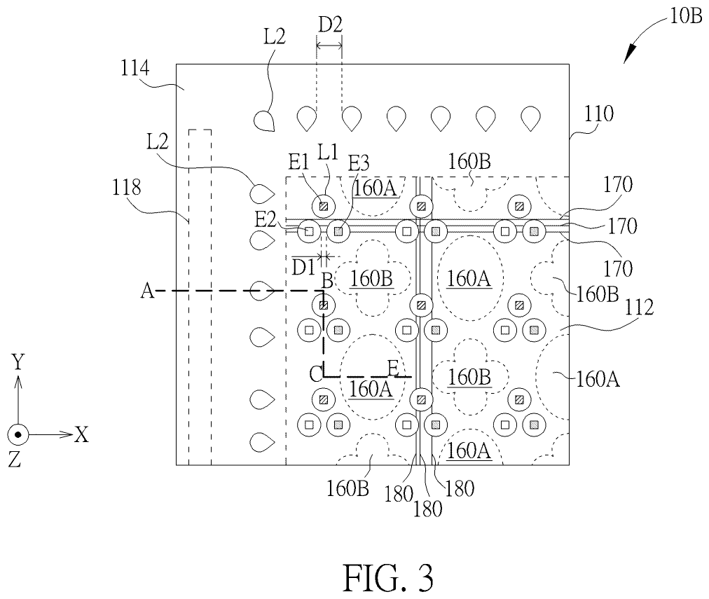

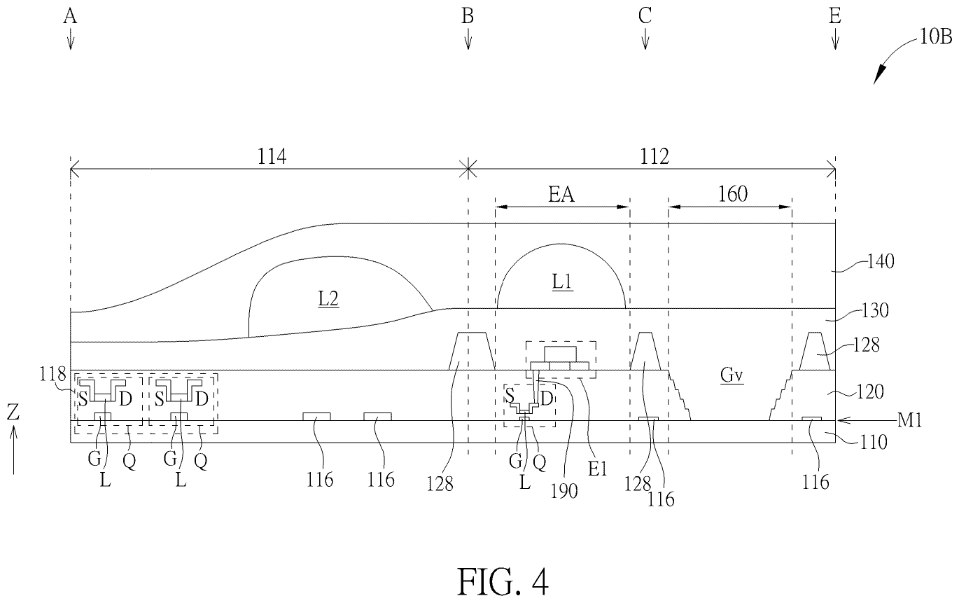

Please refer to FIG. 3 and FIG. 4. FIG. 3 is a top view of an electronic device 10B according to another embodiment of the disclosure, and FIG. 4 is a cross-sectional view of the electronic device 10B in FIG. 3 taken along the dashed line A-B-C-E in FIG. 3. The dashed line A-B-C-E is formed by connecting a plurality of points A, B, C, and E. The electronic device 10B comprises a substrate 110, a plurality of transistors Q, at least one lens unit L1, and at least one lens unit L2. Each transistor Q is arranged on the substrate 110 and has a channel L. The lens units L1 and L2 are both arranged on the substrate 110, and the number of channels L overlapping with the lens unit L1 is different from the number of channels L overlapping with any of the lens units L2. As seen from FIG. 4 in this embodiment, the number of channels L overlapping with the lens unit L1 in FIG. 4 is one, while the number of channels L overlapping with the lens unit L2 in FIG. 4 is zero. Therefore, the number of channels L overlapping with the lens unit L1 among a plurality of transistors Q is less than the number of channels L overlapping with the lens unit L2 among a plurality of transistors Q. Additionally, the profile of the lens unit L1 in the top view is different from the profile of the lens unit L2 in the top view. In the disclosure, “different profiles” means that the two profiles do not present a proportional scaling relationship. Conversely, if the two profiles present a proportional scaling relationship, they are considered to have the “same profile.” As shown in FIG. 3, the profile of the lens unit L1 in the top view is circular, while the profile of the lens unit L2 in the top view shows a teardrop, oval, or non-spherical shape, so the lens units L1 and L2 do not present a proportional scaling relationship. For example, the surface of the lens unit L1 has less curvature variation compared to the lens unit L2. Furthermore, the lens units L1 and L2 are separated from each other. Additionally, the lens unit L2 can extend along directions Y and X.

The area of the electronic device 10B comprises an active region 112 and a peripheral region 114 adjacent to the active region 112. As shown in FIG. 3, in this embodiment, all the lens units L1 are arranged in the active region 112, and all the lens units L2 are arranged in the peripheral region 114. Furthermore, the active region 112 has a plurality of light transmitting areas 160A and 160B surrounding the lens units L1. The plurality of light transmitting areas 160A and 160B surrounding the lens unit L1 can be separated from each other without direct contact or can be connected to each other. Additionally, the plurality of light transmitting areas 160A and 160B surrounding the lens unit L1 can be arranged around the lens unit L1 on at least four sides. In this embodiment, the minimum distance D1 between two adjacent lens units L1 is less than the minimum distance D2 between two adjacent lens units L2. The electronic device 10B may further comprise a driving circuit 118 and a conductive layer M1. The conductive layer M1 is arranged on the substrate 110 and has a plurality of conductive lines 116. The conductive lines 116 are connected to the driving circuit 118, which can drive the transistors Q arranged in the active region 112 through the conductive lines 116. The electronic device 10B may further comprise an insulating layer 120 arranged on the substrate 110 and covering the driving circuit 118 and the conductive layer M1. The insulating layer 120 in the active region 112 can be composed of a plurality of layers and form grooves Gv to constitute the light transmitting areas 160A or 160B. The sidewalls of the grooves Gv can be stepped due to the multi-layer structure of the insulating layer 120. Additionally, the shapes of the light transmitting areas 160A and 160B can be different to reduce light diffraction in the electronic device 10B. In this embodiment, the light transmitting areas 160A and 160B are arranged in an interlaced pattern. Furthermore, the substrate 110, insulating layer 130, and insulating layer 140 can be made of transparent materials, allowing light to pass through the electronic device 10B from the light transmitting areas 160A and 160B within the substrate 110, insulating layer 130, and insulating layer 140. Additionally, the conductive lines 116 and/or the definition layer 128 can be made of opaque materials, and the opaque elements in the electronic device 10B (i.e., elements blocking or reflecting light) can be arranged in areas other than the light transmitting areas 160A and 160B, offsetting them from the light transmitting areas 160A and 160B. The opaque elements can comprise but are not limited to the black matrix (BM), white matrix, pixel definition layer (PDL), and/or metal conductive lines of the electronic device 10B. The electronic device 10B may further comprise a definition layer 128 and a plurality of light-emitting units E1, E2, and E3 arranged on the insulating layer 120. The definition layer 128 can be, but not limited to, a pixel definition layer, and the light-emitting units E1, E2, and E3 can be, but not limited to, light-emitting diodes. The electronic device 10B may further comprise an insulating layer 130 arranged on the insulating layer 120 and covering the definition layer 128 and the light-emitting units E1, E2, and E3. In this embodiment, the lens units L1 and L2 are both arranged on the insulating layer 130. The electronic device 10B may further comprise an insulating layer 140 arranged on the insulating layer 130 and covering the lens units L1 and L2. Each of the light-emitting units E1, E2, and E3 is arranged with a lens unit L1, forming the light-emitting area EA. Therefore, the lens unit L1 overlaps with at least one of the light-emitting units E1, E2, and E3, while the lens unit L2 does not overlap with any of the light-emitting units E1, E2, and E3. Additionally, each light-emitting unit E1, E2, and E3 is connected to the corresponding transistor Q through a conductor 190 and emits light under the control of the transistor Q. The electronic device 10B may further comprise a plurality of scan lines 170 and a plurality of data lines 180, which do not overlap with the light transmitting areas 160A and 160B. The driving circuit 118 can drive the transistors Q arranged in the active region 112 through the scan lines 170.

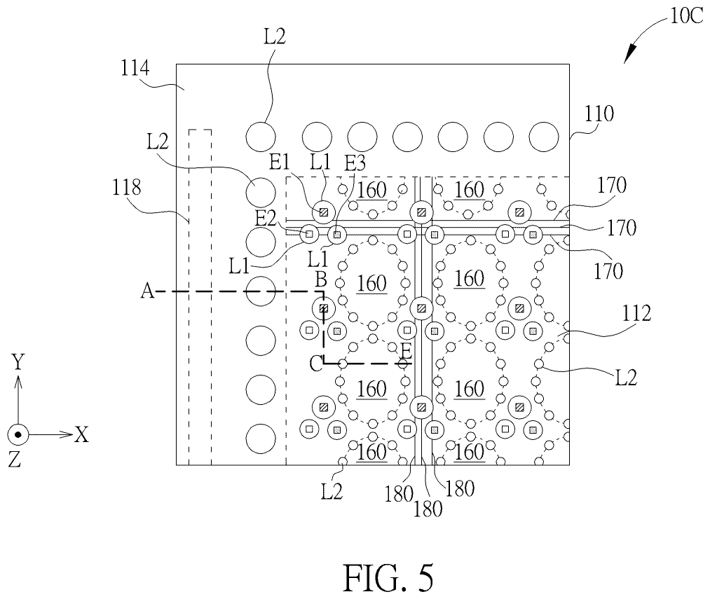

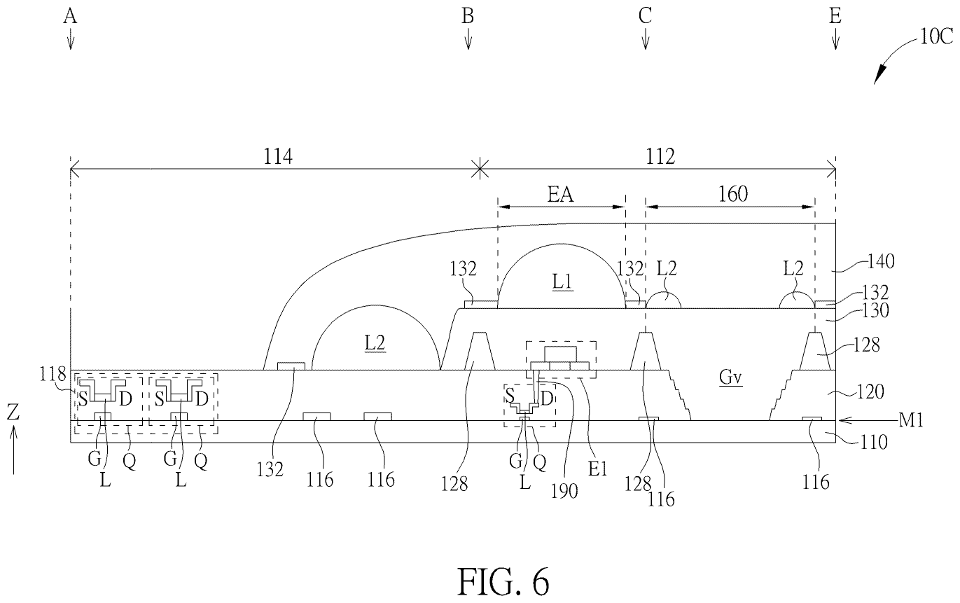

Please refer to FIG. 5 and FIG. 6. FIG. 5 is a top view of an electronic device 10C according to another embodiment of the disclosure, and FIG. 6 is a cross-sectional view of the electronic device 10C in FIG. 5 taken along the dashed line A-B-C-E in FIG. 5. The electronic device 10C comprises a substrate 110, a plurality of transistors Q, at least one lens unit L1, and at least one lens unit L2. Each transistor Q is arranged on the substrate 110 and has a channel L. The lens units L1 and L2 are both arranged on the substrate 110, and the number of channels L overlapping with the lens unit L1 is different from the number of channels L overlapping with any of the lens units L2. As seen from FIG. 6 in this embodiment, the number of channels L overlapping with the lens unit L1 in FIG. 6 is one, while the number of channels L overlapping with the lens unit L2 in FIG. 6 is zero. As shown in FIG. 5, the profiles of the lens units L1 and L2 in the top view are both circular.

The area of the electronic device 10C comprises an active region 112 and a peripheral region 114 adjacent to the active region 112. As shown in FIG. 5, in this embodiment, all the lens units L1 are arranged in the active region 112, while the lens units L2 are partially arranged in the peripheral region 114 and partially in the active region 112. Additionally, the active region 112 has a plurality of light transmitting areas 160 surrounding the lens units L1. The electronic device 10C may further comprise a driving circuit 118 and a conductive layer M1. The conductive layer M1 is arranged on the substrate 110 and has a plurality of conductive lines 116. The conductive lines 116 are connected to the driving circuit 118, which can drive the transistors Q arranged in the active region 112 through the conductive lines 116. The electronic device 10C may further comprise an insulating layer 120 arranged on the substrate 110 and covering the driving circuit 118 and the conductive layer M1. The insulating layer 120 in the active region 112 can be composed of a plurality of layers and form grooves Gv to constitute the light transmitting areas 160. The sidewalls of the grooves Gv can be stepped due to the multi-layer structure of the insulating layer 120. The electronic device 10C may further comprise a definition layer 128 and a plurality of light-emitting units E1, E2, and E3 arranged on the insulating layer 120. The electronic device 10C may further comprise an insulating layer 130 arranged on the insulating layer 120 and covering the definition layer 128 and the light-emitting units E1, E2, and E3. In this embodiment, the lens units L2 within the peripheral region 114 are all arranged on the insulating layer 120, while the lens units L1 and L2 within the active region 112 are all arranged on the insulating layer 130. The electronic device 10C may further comprise a lens definition layer 132 arranged on the insulating layer 130 and formed between each of the lens units L1 and L2. The electronic device 10C may further comprise an insulating layer 140 arranged on the insulating layer 130 and covering the lens units L1, L2, and the lens definition layer 132. Each of the light-emitting units E1, E2, and E3 is arranged with a lens unit L1, forming the light-emitting area EA. Additionally, the edge of the light transmitting area 160 can overlap with a plurality of lens units L2, but the disclosure is not limited thereto. For example, the edge of the light transmitting area 160 can overlap with a single lens unit L2. The edge of the light transmitting area 160 can be the junction between opaque materials (e.g., conductive lines 116) and transparent materials (e.g., insulating layer 120), or, when the insulating layer 120 is an opaque material, the lower or upper bottom of the grooves Gv. By arranging the edge of the light transmitting area 160 to overlap with a plurality of lens units L2, the edge of the light transmitting area 160 can be roughened, thereby reducing light diffraction. Furthermore, the area of the lens unit L1 arranged on the light-emitting unit E1 is larger than the area of the lens unit L1 arranged on the light-emitting unit E2, and larger than the area of the lens unit L1 arranged on the light-emitting unit E3. The area of each lens unit L1 or L2 refers to the range observed when viewing the electronic device 10C from a top view (such as viewing the electronic device 10C along the opposite direction of Z in FIG. 5).

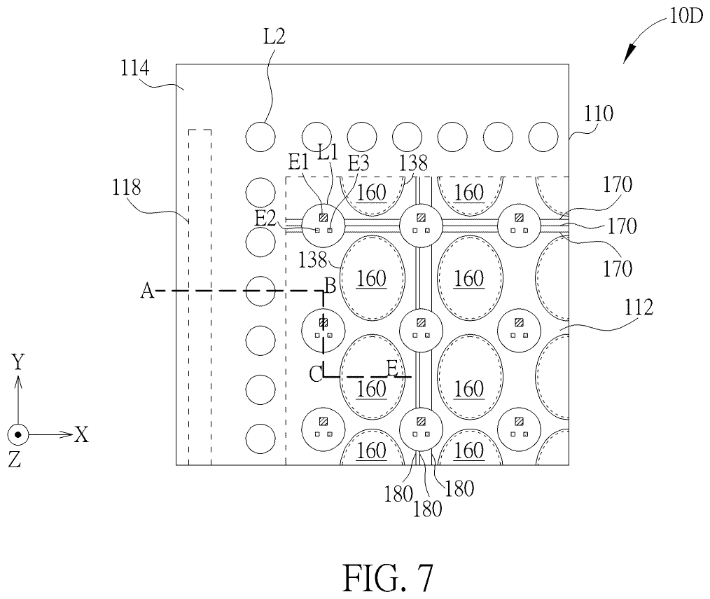

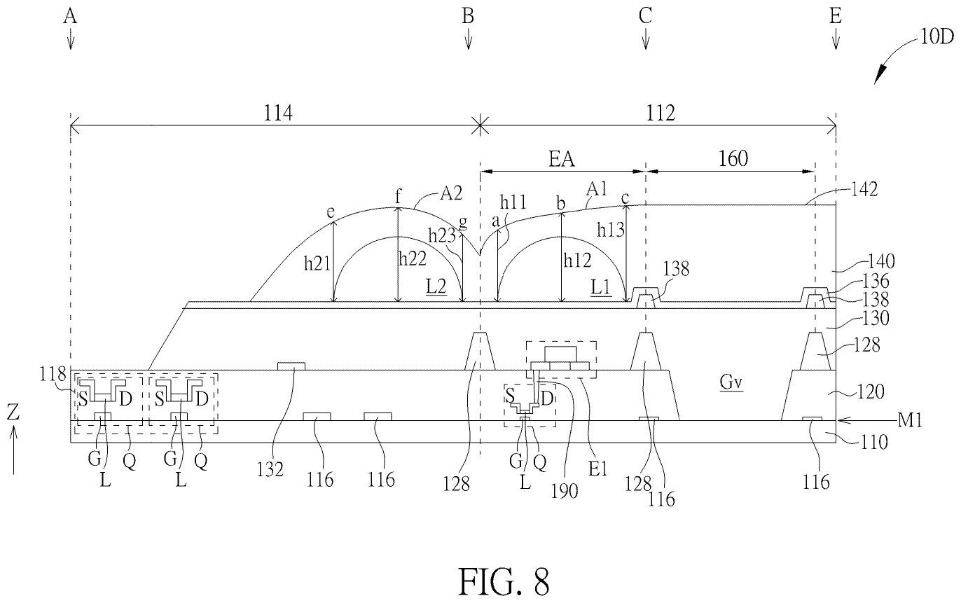

Please refer to FIG. 7 and FIG. 8. FIG. 7 is a top view of an electronic device 10D according to another embodiment of the disclosure, and FIG. 8 is a cross-sectional view of the electronic device 10D in FIG. 7 taken along the dashed line A-B-C-E in FIG. 7. The electronic device 10D comprises a substrate 110, a plurality of transistors Q, at least one lens unit L1, and at least one lens unit L2. Each transistor Q is arranged on the substrate 110 and has a channel L. The lens units L1 and L2 are both arranged on the substrate 110, and the number of channels L overlapping with the lens unit L1 is different from the number of channels L overlapping with any of the lens units L2. As seen from FIG. 8 in this embodiment, the number of channels L overlapping with the lens unit L1 in FIG. 8 is one, while the number of channels L overlapping with the lens unit L2 in FIG. 8 is zero. As shown in FIG. 7, the profiles of the lens units L1 and L2 in the top view are both circular.

Please refer to FIG. 7 and FIG. 8. FIG. 7 is a top view of an electronic device 10D according to another embodiment of the disclosure, and FIG. 8 is a cross-sectional view of the electronic device 10D in FIG. 7 taken along the dashed line A-B-C-E in FIG. 7. The electronic device 10D comprises a substrate 110, a plurality of transistors Q, at least one lens unit L1, and at least one lens unit L2. Each transistor Q is arranged on the substrate 110 and has a channel L. The lens units L1 and L2 are both arranged on the substrate 110, and the number of channels L overlapping with the lens unit L1 is different from the number of channels L overlapping with any of the lens units L2. As seen from FIG. 8 in this embodiment, the number of channels L overlapping with the lens unit L1 in FIG. 8 is one, while the number of channels L overlapping with the lens unit L2 in FIG. 8 is zero. As shown in FIG. 7, the profiles of the lens units L1 and L2 in the top view are both circular. The area of the electronic device 10D comprises an active region 112 and a peripheral region 114 adjacent to the active region 112. As shown in FIG. 5, in this embodiment, all the lens units L1 are arranged in the active region 112, while the lens units L2 are partially arranged in the peripheral region 114 and partially in the active region 112. Additionally, the active region 112 has a plurality of light transmitting areas 160 surrounding the lens units L1. The electronic device 10D may further comprise a driving circuit 118 and a conductive layer M1. The conductive layer M1 is arranged on the substrate 110 and has a plurality of conductive lines 116. The conductive lines 116 are connected to the driving circuit 118, which can drive the transistors Q arranged in the active region 112 through the conductive lines 116. The electronic device 10D may further comprise an insulating layer 120 arranged on the substrate 110 and covering the driving circuit 118 and the conductive layer M1. The insulating layer 120 in the active region 112 is formed with grooves Gv to constitute the light transmitting areas 160. The electronic device 10D may further comprise a definition layer 128 and a plurality of light-emitting units E1, E2, and E3 arranged on the insulating layer 120. The electronic device 10D may further comprise an insulating layer 130 arranged on the insulating layer 120 and covering the definition layer 128 and the light-emitting units E1, E2, and E3. The electronic device 10D may further comprise an annular structure 138 arranged on the insulating layer 130 and surrounding the edge of the light transmitting area 160 to roughen the edge of the light transmitting area 160, thereby reducing light diffraction. The electronic device 10D may further comprise an insulating layer 136 arranged on the insulating layer 120 and the annular structure 138. In this embodiment, the lens units L1 and L2 are both arranged on the insulating layer 136. The electronic device 10D may further comprise an insulating layer 140 arranged on the insulating layer 136 and covering the lens units L1, L2, and the insulating layer 136. Each lens unit L1 covers one light-emitting unit E1, one light-emitting unit E2, and one light-emitting unit E3, forming the light-emitting area EA. In this embodiment, the top surface 142 of the insulating layer 140 is recessed in the direction opposite to Z at the junction of the active region 112 and the peripheral region 114, and the top surface 142 of the insulating layer 140 in the peripheral region 114 is arcuate and convex in the direction of Z. Furthermore, the profile of the overlapping portion A1 of the top surface 142 of the insulating layer 140 with the lens unit L1 is different from the profile of the overlapping portion A2 of the top surface 142 of the insulating layer 140 with the lens unit L2. The methods to determine the profile can be described as follows, but are not limited thereto:

Method 1: The profiles of the overlapping portions A1 and A2 can be measured by Atomic Force Microscopy (AFM).

Method 2: When the distance between the overlapping portion A1 and the insulating layer 136 is different from the distance between the overlapping portion A2 and the insulating layer 136, it can be determined that the profile of the overlapping portion A1 is different from the profile of the overlapping portion A2. For example, in FIG. 8, in a cross-section, the distances between the overlapping portion A1 and the left side, bottom center point, and right side of the lens unit L1 are h11, h12, and h13, respectively, while the distances between the overlapping portion A2 and the left side, bottom center point, and right side of the lens unit L2 are h21, h22, and h23, respectively. The absolute difference between distances h11, h12, and h13 is greater than the absolute difference between distances h21, h22, and h23. Using the bottom center point of the lens unit as an example, the absolute difference between the distances h12 and h11 is greater than the absolute difference between the distances h22 and h21, and the absolute difference between the distances h12 and h13 is smaller than the absolute difference between the distances h22 and h23. This can determine that the profile of the overlapping portion A1 is different from the profile of the overlapping portion A2.

Method 3: When the curvature of the overlapping portion A1 is different from the curvature of the overlapping portion A2, it can be determined that the profile of the overlapping portion A1 is different from the profile of the overlapping portion A2. The curvature of the overlapping portion A1 can be determined by three different points of the overlapping portion A1 in the electronic device 10D, and the curvature of the overlapping portion A2 can be determined by three different points of the overlapping portion A2 in the electronic device 10D. For example, the points a, b, and c of the left side, bottom center point, and right side of the lens unit L1 are projected along direction Z onto the overlapping portion A1, and the points e, f, and g of the left side, bottom center point, and right side of the lens unit L2 are projected along direction Z onto the overlapping portion A2. The curvature formed by points a, b, and c is different from the curvature formed by points e, f, and g, so it can be determined that the profile of the overlapping portion A1 is different from the profile of the overlapping portion A2.

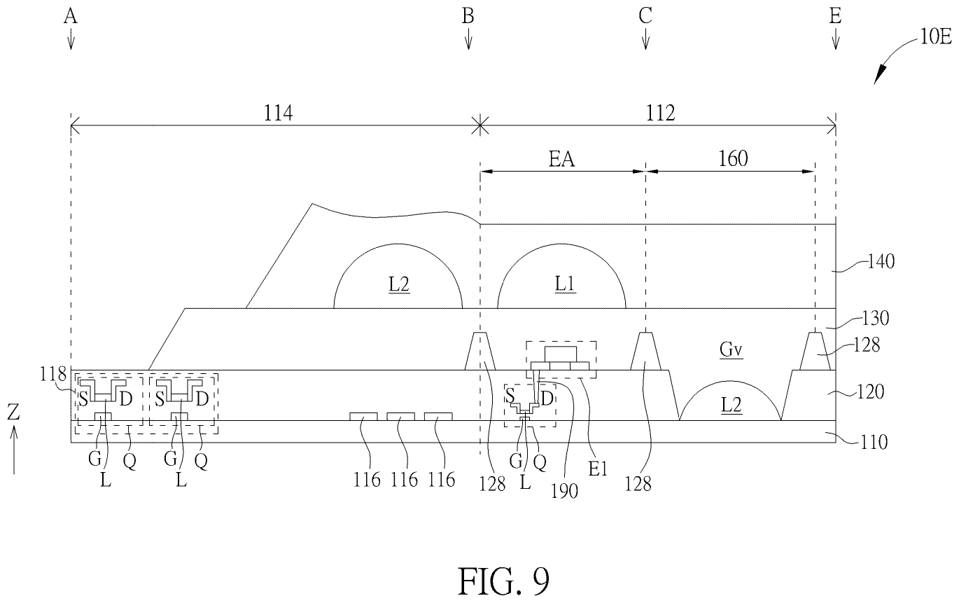

Please refer to FIG. 9. FIG. 9 is a cross-sectional view of an electronic device 10E according to another embodiment of the disclosure. The structure of the electronic device 10E is similar to that of the electronic device 10D, with the main differences being that the electronic device 10E does not comprise the insulating layer 136 and the annular structure 138. Additionally, in the active region 112, the lens unit L2 of the electronic device 10E is arranged within the light transmitting area 160 and formed in the groove Gv of the insulating layer 120 on the substrate 110. Therefore, in the normal direction of the substrate 110 (i.e., direction Z), the distance between the lens unit L1 and the substrate 110 is different from the distance between the lens unit L2 in the active region 112 and the substrate 110. Furthermore, the top surface of the insulating layer 140 in the peripheral region 114 has a wavy profile.

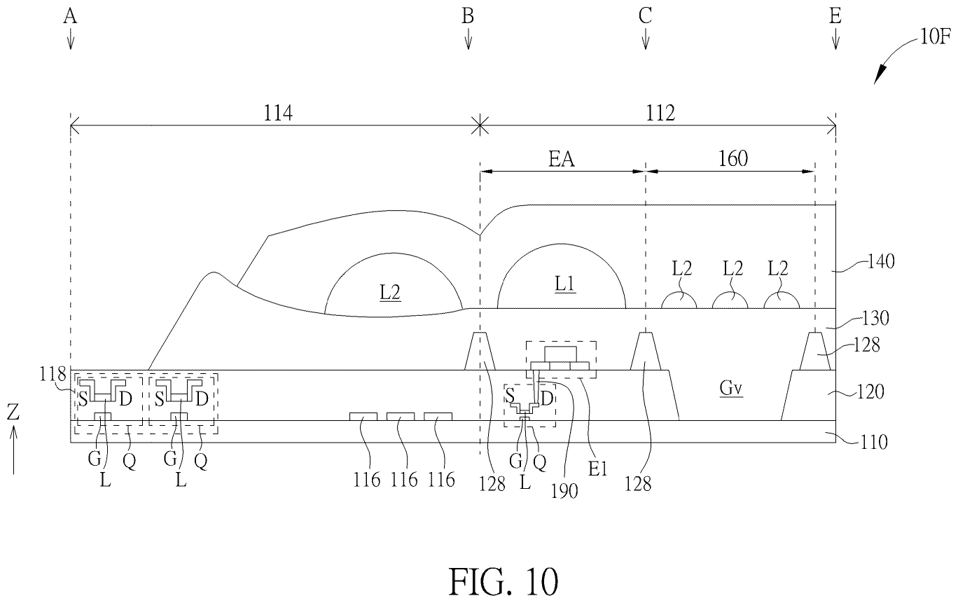

Please refer to FIG. 10. FIG. 10 is a cross-sectional view of an electronic device 10F according to another embodiment of the disclosure. The structure of the electronic device 10F is similar to that of the electronic device 10E, with the main difference being that in the active region 112, the lens unit L2 of the electronic device 10F is arranged within the light transmitting area 160 and formed on the insulating layer 130. Additionally, the top surface of the insulating layer 140 in the peripheral region 114 is arcuate and convex in the direction of Z, while the top surface of the insulating layer 130 in the peripheral region 114 is arcuate and concave in the opposite direction of Z. The lens unit L2 overlaps with one of the light transmitting areas 160.

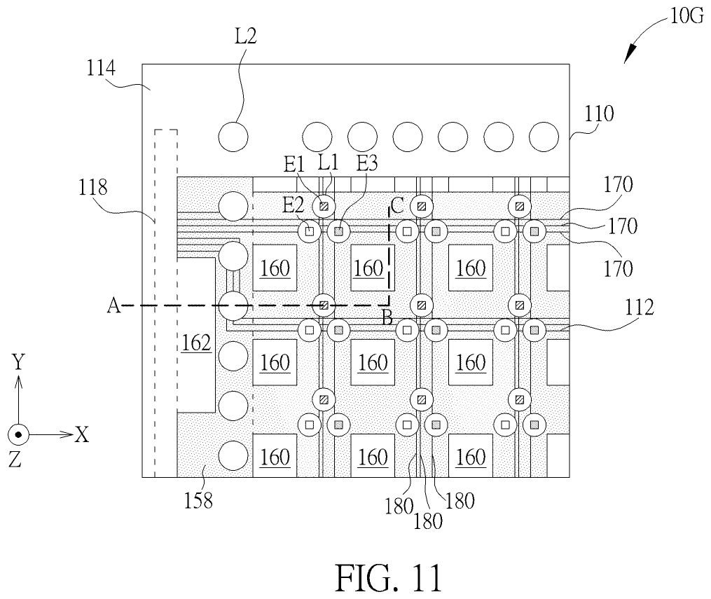

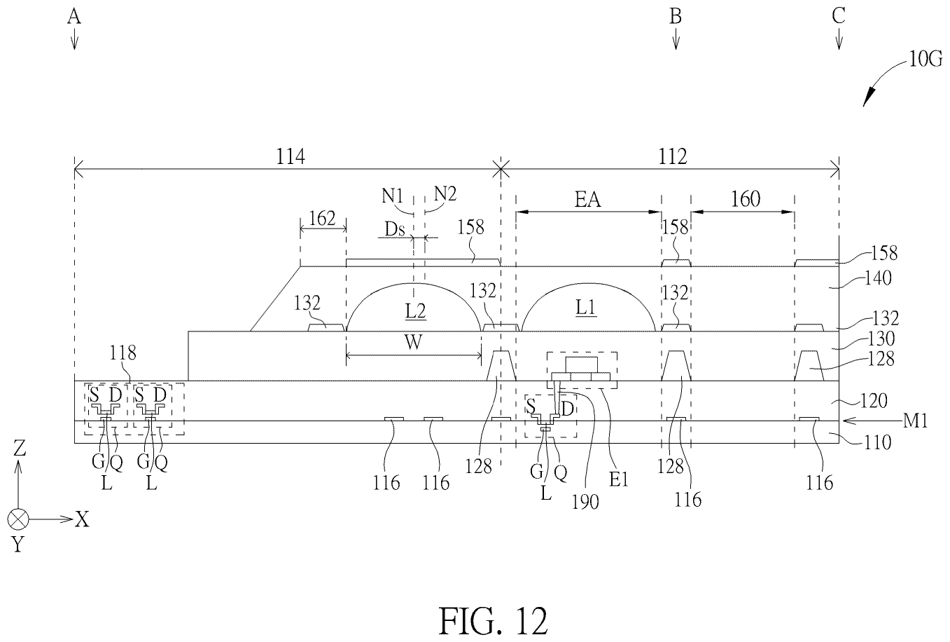

Please refer to FIG. 11 and FIG. 12. FIG. 11 is a top view of an electronic device 10G according to another embodiment of the disclosure, and FIG. 12 is a cross-sectional view of the electronic device 10G in FIG. 11 taken along the dashed line A-B-C in FIG. 11. The electronic device 10G comprises a substrate 110, a plurality of transistors Q, at least one lens unit L1, and at least one lens unit L2. Each transistor Q is arranged on the substrate 110 and has a channel L. The lens units L1 and L2 are both arranged on the substrate 110, and the number of channels L overlapping with the lens unit L1 is different from the number of channels L overlapping with any of the lens units L2. As seen from FIG. 12 in this embodiment, the number of channels L overlapping with the lens unit L1 in FIG. 12 is one, while the number of channels L overlapping with the lens unit L2 in FIG. 12 is zero. As shown in FIG. 11, the profiles of the lens units L1 and L2 in the top view are both circular and can also be elliptical.

The area of the electronic device 10G comprises an active region 112 and a peripheral region 114 adjacent to the active region 112. As shown in FIG. 11, in this embodiment, all the lens units L1 are arranged in the active region 112, while all the lens units L2 are arranged in the peripheral region 114. Additionally, the active region 112 has a plurality of light transmitting areas 160 surrounding the lens units L1. The electronic device 10G may further comprise a driving circuit 118 and a conductive layer M1. The conductive layer M1 is arranged on the substrate 110 and has a plurality of conductive lines 116. The conductive lines 116 are connected to the driving circuit 118, which can drive the transistors Q arranged in the active region 112 through the conductive lines 116. The electronic device 10G may further comprise an insulating layer 120 arranged on the substrate 110 and covering the driving circuit 118 and the conductive layer M1. The electronic device 10G may further comprise a definition layer 128 and a plurality of light-emitting units E1, E2, and E3 arranged on the insulating layer 120. The electronic device 10G may further comprise an insulating layer 130 arranged on the insulating layer 120 and covering the definition layer 128 and the light-emitting units E1, E2, and E3. In this embodiment, the lens units L1 and L2 are both arranged on the insulating layer 130. The electronic device 10G may further comprise a lens definition layer 132 arranged on the insulating layer 130 and formed between each of the lens units L1 and L2. The electronic device 10G may further comprise an insulating layer 140 arranged on the insulating layer 130 and covering the lens units L1 and L2. Each of the light-emitting units E1, E2, and E3 is arranged with a lens unit L1, while a shading layer 158 is arranged above the lens definition layer 132 and each lens unit L2, forming the light-emitting area EA, the light transmitting area 160, and the light transmitting area 162 in the regions outside the shading layer 158. The light transmitting area 160 is formed in the active region 112, while the light transmitting area 162 is formed in the peripheral region 114. The area of the light transmitting area 160 is different from the area of the light transmitting area 162. For example, the area of the light transmitting area 162 can be between 1.1 and 10 times the area of the light transmitting area 160. This can balance the overall transparency between the active region 112 and the peripheral region 114, enhancing the overall viewing experience of the device. Additionally, as shown in the cross-sectional view of the electronic device 10G in FIG. 12, the center point of the shading layer 158 in the peripheral region 114 is offset by Ds towards the active region 112 relative to the center point of the lens unit L2. The offset Ds can be greater than 0.1 times the width W of the lens unit L2 (i.e., Ds≥0.1W). This arrangement can further reduce side light leakage in the electronic device 10G. Furthermore, in the cross-sectional view of the electronic device 10G in FIG. 12, the center line N1 of the lens unit L2 may not overlap with the center line N2 of the shading layer 158. However, in other embodiments, the center line N1 may overlap with the center line N2. The center line N1 passes through the center point of the lens unit L2 and is parallel to the normal direction (i.e., direction Z) of the lens unit L2, while the center line N2 passes through the center point of the shading layer 158 and is parallel to the normal direction (i.e., direction Z) of the shading layer 158.

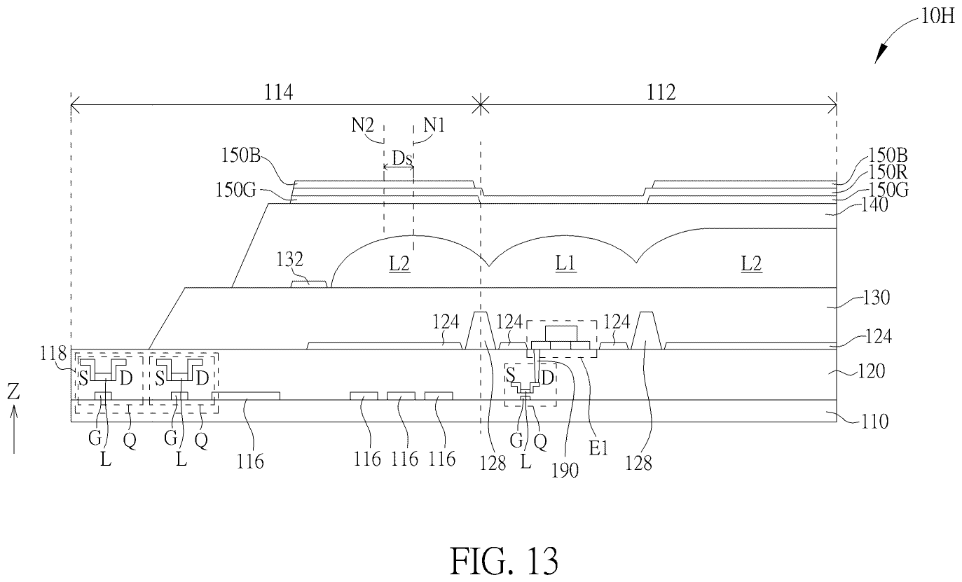

Please refer to FIG. 13. FIG. 13 is a cross-sectional view of an electronic device 10H according to another embodiment of the present disclosure. The structure of the electronic device 10H is similar to that of the electronic device 10G in FIG. 12, and the main differences between the two are as follows: (1) The electronic device 10H further comprises a light-shielding layer 124 formed on the insulating layer 120 to prevent internal reflection of the lens units L1 and L2; (2) The lens units L1 and L2 of the electronic device 10H are connected to each other without a lens definition layer 132 therebetween; and (3) The electronic device 10H further comprises a plurality of color filters 150R, 150G, and 150B disposed on the insulating layer 140 without a light-shielding layer 158. The width of the lens unit L2 is smaller than the width of each color filter 150R, 150G, and 150B on the lens unit L2. In the cross-sectional view of the electronic device 10H as shown in FIG. 13, the centerline N1 of the lens unit L2 is closer to the lens unit L1 than the centerlines N2 of the color filters 150G and 150B. Here, the centerline N1 passes through the center point of the lens unit L2 and is parallel to the normal direction (i.e., the Z direction) of the lens unit L2, while the centerline N2 passes through the center points of the color filters 150G and 150B and is parallel to the normal direction (i.e., the Z direction) of the color filters 150G and 150B.

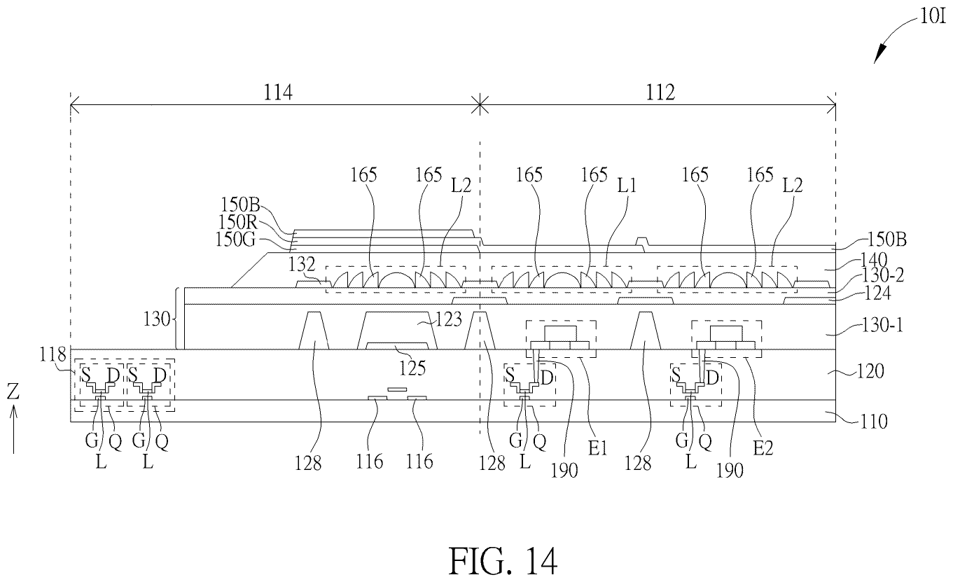

Please refer to FIG. 14. FIG. 14 is a cross-sectional view of an electronic device 10I according to another embodiment of the present disclosure. The structure of the electronic device 10I is similar to that of the electronic device 10G in FIG. 12, and the main differences between the two are as follows: (1) The insulating layer 130 of the electronic device 10I comprises two sub-insulating layers 130-1 and 130-2; (2) The electronic device 10I further comprises a light-shielding layer 124 formed on the sub-insulating layer 130-1 of the insulating layer 130 and covered by the sub-insulating layer 130-2, and is located above the definition layer 128; (3) The lens units L1 and L2 of the electronic device 10I are Fresnel lenses and each has a plurality of thread structures 165; (4) The electronic device 10I further comprises a plurality of the color filters 150R, 150G, and 150B disposed on the insulating layer 140 without a light-shielding layer 158; (5) The electronic device 10I further comprises a dummy pattern 123 disposed on the insulating layer 120 and between the definition layer 128 to enhance the structural strength of the electronic device 10I; and (6) The cross-sectional view of the electronic device 10I further illustrates a light-emitting unit E2, and its corresponding transistor Q, lens unit L1, and the color filter 150B. The width of the lens unit L2 is smaller than the width of each color filter 150R, 150G, and 150B on the lens unit L2. When the lens units L1 and L2 are implemented as Fresnel lenses, the thickness of the electronic device 10I can be reduced, and when the lens definition layer 132 is a metal mesh and has a touch function, the touch sensitivity can be increased. In addition, a metal layer 125 can be disposed in the dummy pattern 123, and the electronic device 10I can transmit signals through the metal layer 125.

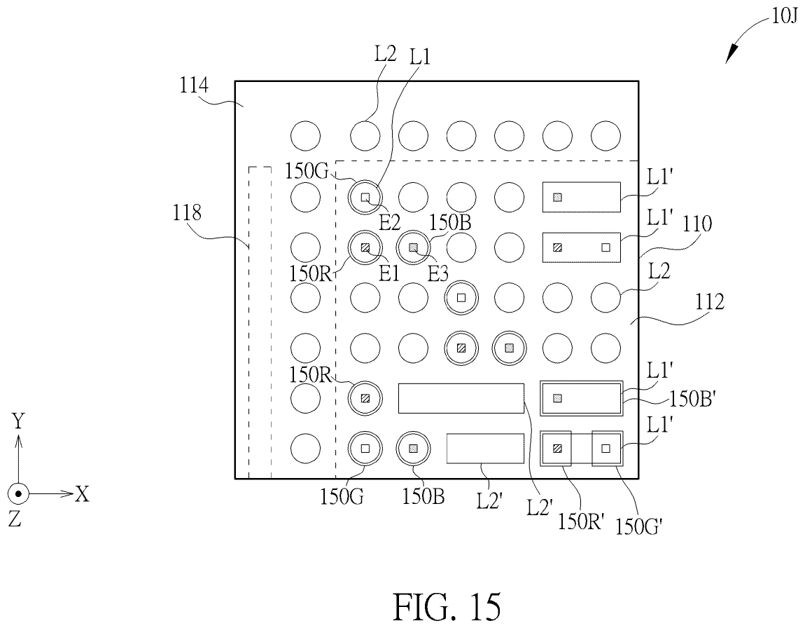

In the aforementioned embodiments, the profiles of the lens units L1 and L2 in the top view of the electronic device can be circular, while in other embodiments of the disclosure, the profiles of the lens units L1 and L2 in the top view of the electronic device can be rectangular. Please refer to FIG. 15. FIG. 15 is a top view of an electronic device 10J according to another embodiment of the disclosure. The electronic device 10J comprises a plurality of light-emitting units E1, E2, and E3, and a plurality of the lens units L1, L2, L1′, and L2′. Among them, the profiles of the lens units L1 and L2 in the top view are circular, while the profiles of the lens units L1′ and L2′ in the top view are rectangular. Each of the lens units L1 and L1′ corresponds to one or more of the light-emitting units E1, E2, and E3, while the lens units L2 and L2′ do not correspond to any light-emitting units. The viewing angle of the light emitted by the lens unit L1′ is wider than the viewing angle of the light emitted by the lens unit L1. Additionally, it is worth noting that the shapes of the lens units L1, L2, L1′, and L2′ in the three-dimensional view of the electronic device 10J are cylindrical. Furthermore, in the top view of the electronic device 10J, each lens unit L1 is completely covered by the corresponding color filter 150R, 150G, or 150B, and the area of each lens unit L1 is smaller than the area of the corresponding color filter 150R, 150G, or 150B. The lens unit L1′ is completely covered by the corresponding color filter 150B′, and the area of the lens unit L1′ is smaller than the area of the corresponding color filter 150B′. Additionally, the range of color filter 150R′ exceeds the range of the corresponding lens unit L1′, and the range of color filter 150G′ exceeds the range of the corresponding lens unit L1′.

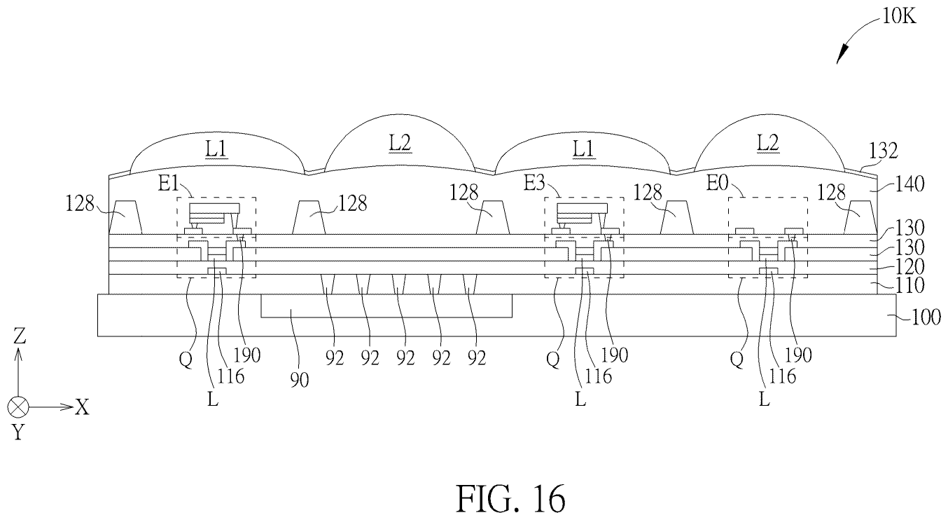

Please refer to FIG. 16. FIG. 16 is a cross-sectional view of an electronic device 10K according to another embodiment of the disclosure. The electronic device 10K comprises a substrate 110, a plurality of transistors Q, a plurality of the lens units L1, a plurality of the lens units L2, an insulating layer 120, a definition layer 128, an insulating layer 130, a lens definition layer 132, an insulating layer 140, light-emitting units E1 and E2, and a circuit 90. The insulating layer 140 has an upper surface that is convex in the Z direction as it follows the contours of the lens units L1 and L2. Additionally, the plurality of lens units L1 and L2 can have different shapes; for example, the plurality of lens units L1 and L2 can have different upper surface curvatures or lower surface curvatures. The electronic device 10K can control the direction of the light emitted by the light-emitting units E1 and E3 by matching the refractive indices between the insulating layer 140 and the lens units L1 and L2. For instance, the refractive index of the insulating layer 140 can be between 1.3 and 1.5, while the refractive indexes of the lens units L1 and L2 can be between 1.5 and 1.9. Moreover, an integrated circuit 90 is arranged below the substrate 110 and is aligned with one of the lens units L2. The integrated circuit 90 can be connected to the transistors Q via a conductive line 92. The user can view the integrated circuit 90 and the conductive line 92 through the lens unit L2 to confirm that the integrated circuit 90 and the conductive line 92 are properly connected. Additionally, the lens unit L2 on the right side of FIG. 16 corresponds to a set of functional pads E0. The functional pads E0 can be used to establish related repair circuits or detection circuits when there is a need to repair or inspect the electronic device 10K, but this is not limited to such functionality. In other embodiments, the electronic device may comprise the light-emitting unit E1 or E3 and the integrated circuit 90, but this is not limited to such configurations. The electronic device 10K may further comprise another substrate 100.

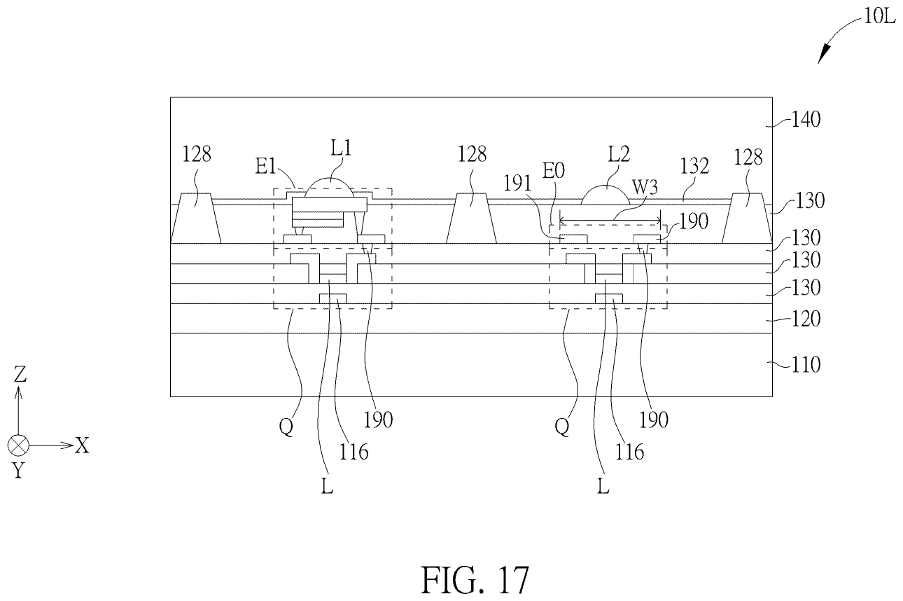

Please refer to FIG. 17. FIG. 17 is a cross-sectional view of an electronic device 10L according to another embodiment of the disclosure. The electronic device 10L comprises a substrate 110, a transistor Q, lens units L1 and L2, an insulating layer 120, a definition layer 128, an insulating layer 130, a lens definition layer 132, an insulating layer 140, a light-emitting unit E1, and a functional pad E0. The functional pad E0 may have two conductive structures 190 and 191, and the width W3 of the functional pad E0 can be defined as the distance in the X direction between the two farthest ends of the conductive structures 190 and 191. In other embodiments, the functional pad E0 may have a single conductive structure 190 or 191, and the width of the functional pad E0 is defined as the width of this conductive structure 190 or 191 in the X direction. Additionally, the lens unit L1 is arranged on the light-emitting unit E1, and the width of the lens unit L1 is smaller than the width of the light-emitting unit E1. The lens unit L2 is arranged on the functional pad E0, and the width of the lens unit L2 is smaller than the width of the functional pad E0.

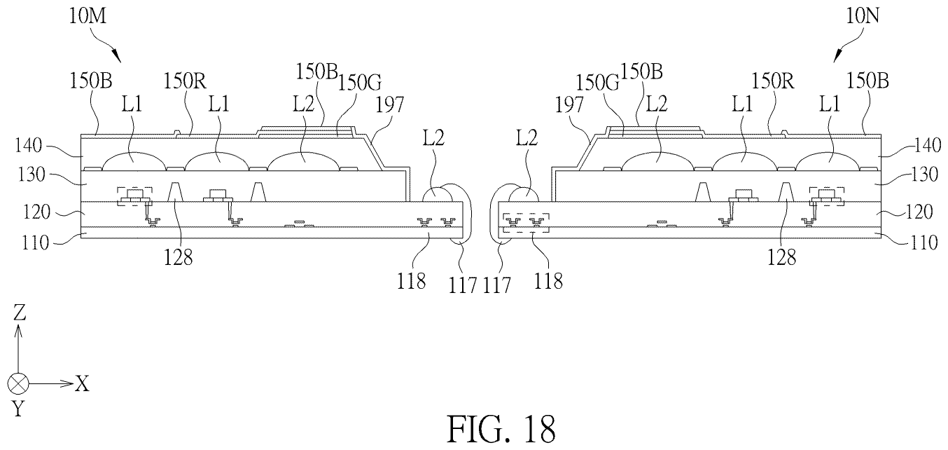

Please refer to FIG. 18. FIG. 18 is a cross-sectional view of two electronic devices 10M and 10N according to another embodiment of the disclosure. The electronic devices 10M and 10N respectively comprise a substrate 110, a transistor Q, lens units L1 and L2, an insulating layer 120, a definition layer 128, an insulating layer 130, a lens definition layer 132, an insulating layer 140, light-emitting units E1 and E3, a driving circuit 118, and a plurality of color filters 150R, 150G, and 150B. The electronic devices 10M and 10N further comprise side functional layers 117 formed on the sides of the substrate 110 and the insulating layer 120. Additionally, the lens units L2 are arranged on the sides of the substrate 110 and the insulating layer 120 to strengthen the structural integrity of the side functional layers 117. The electronic devices 10M and 10N can be connected to each other through the side functional layers 117. The side functional layers 117 can comprise, but not limited to, side wiring, side protective layers, side adhesive layers, or side shading layers. Furthermore, the electronic devices 10M and 10N respectively comprise shading layers 197, arranged on the sides of the insulating layers 130 and 140, to reduce side light leakage of the electronic devices 10M and 10N. Additionally, the width of the lens units L2 arranged on the sides of the electronic devices 10M and 10N can be greater than the width of the lens units L1.

In the above description, the width, height, pitch, spacing, minimum distance, and other dimensions of the components can be measured using Optical Microscopy (OM), Scanning Electron Microscopy (SEM), Transmission Electron Microscopy (TEM), Scanning Tunneling Microscopy (STM), or Atomic Force Microscopy (AFM).

The electronic device disclosed in the above embodiments can enhance its structural strength by arranging the lens units L2 in the peripheral region 114 of the substrate. This also improves the shape stability and uniformity between the lens units L1 and L2, thereby enhancing the overall optical performance of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a plurality of transistors disposed on the substrate, and each of the transistors having a channel;
a first lens unit disposed on the substrate; and
a second lens unit disposed on the substrate;
wherein a quantity of channels of the plurality of transistors overlapping with the first lens unit is different from a quantity of channels of the plurality of transistors overlapping with the second lens unit.

2. The electronic device of claim 1, further comprising a plurality of light emitting units disposed on the substrate, wherein the first lens unit is overlapped with at least one of the plurality of light emitting units, the second lens unit is not overlapped with the plurality of light emitting units, the quantity of channels of the plurality of transistors overlapping with the first lens unit is less than the quantity of channels of the plurality of transistors overlapping with the second lens unit.

3. The electronic device of claim 1, further comprising a plurality of light emitting units disposed on the substrate, wherein the first lens unit is overlapped with at least one of the plurality of light emitting units, the second lens unit is not overlapped with the plurality of light emitting units, wherein the first lens unit and the second lens unit are separate from each other.

4. The electronic device of claim 1, further comprising a plurality of light emitting units disposed on the substrate, wherein the first lens unit is overlapped with at least one of the plurality of light emitting units, the second lens unit is not overlapped with the plurality of light emitting units, wherein the first lens unit and the second lens unit are different in shape and the second lens unit is extending along a direction.

5. The electronic device of claim 1, further comprising a conductive layer disposed on substrate and having a plurality of conductive lines, wherein a pitch of two adjacent ones of the plurality of conductive lines under the first lens unit is less than a pitch of another two adjacent ones of the plurality of conductive lines under the second lens unit.

6. The electronic device of claim 1, wherein in a normal direction of the substrate, a distance between the first lens unit and the substrate is different from a distance between the second lens unit and the substrate.

7. The electronic device of claim 1, wherein an area of the electronic device comprises an active region, a peripheral region adjacent to the active region, a plurality of first lens units in the active region and a plurality of second lens unit disposed in the peripheral region, wherein a minimum distance of two adjacent ones of the plurality of first lens units is less than a minimum distance of two adjacent ones of the plurality of second lens units.

8. The electronic device of claim 1, further comprising an insulating layer disposed on the first lens unit and the second lens unit and having a top surface, wherein a profile of a portion of the top surface overlapped with the first lens unit is different from a profile of another portion of the top surface overlapped with the second lens unit.

9. The electronic device of claim 1, wherein an area of the electronic device comprises an active region and a peripheral region adjacent to the active region, the active region has a plurality of light transmitting areas surrounding the first lens unit.

10. The electronic device of claim 9, wherein the peripheral region has a plurality of light transmitting areas, an area of one of the plurality of the light transmitting areas of the active region is different from an area of one of the plurality of the light transmitting areas of the peripheral region.

11. The electronic device of claim 1, wherein an area of the electronic device comprises an active region and a peripheral region adjacent to the active region, the active region has a plurality of light transmitting areas, and the first lens unit is overlapped with one of the plurality of light transmitting areas.

12. The electronic device of claim 1, wherein an area of the light emitting device comprises an active region and a peripheral region adjacent to the active region, the active region has a plurality of light transmitting areas, the second lens unit is overlapped with an edge of one of the plurality of light transmitting areas.

13. The electronic device of claim 1, further comprising a red color filter, a blue color filter and a green color filter, wherein one of the red color filter, the blue color filter and the green color filter is disposed on the first lens unit, and at least two of the red color filter, the blue color filter and the green color filter are disposed on the second lens unit.

14. The electronic device of claim 1, further comprising a color filter disposed on the first lens unit, and another color filter disposed on the second lens unit, wherein the color filter is overlapped with the another color filter.

15. The electronic device of claim 14, wherein the color filter is overlapped with the first lens unit and the second lens unit.

16. The electronic device of claim 15, wherein the another color filter and the color filter are different in color.

17. The electronic device of claim 1, further comprising a color filter disposed on the second lens unit, wherein in a cross section view, a width of the second lens unit is less than a width of the color filter.

18. The electronic device of claim 1, further comprising a color filter disposed on the second lens unit, wherein in a cross section view, a center line of the second lens unit is closer to the first lens unit than a center line of the color filter.

19. The electronic device of claim 1, wherein the first lens unit and the second lens unit are different in shape.

20. The electronic device of claim 1, wherein an area of the electronic device comprises an active region and a peripheral region adjacent to the active region, the active region has a first light transmitting area and a second light transmitting area, and the first light transmitting area and the second light transmitting area are different in shape.
